(19) United States
(12) Patent Application Publication
(10) Pub. No.: US 2025/0204013 A1
(43) Pub. Date: Jun. 19, 2025

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Yuma OKAMOTO, Ibo Hyogo (JP); Hiroyuki IRIFUNE, Ibo Hyogo (JP)

(21) Appl. No.: 19/066,063

(22) Filed: Feb. 27, 2025

Related U.S. Application Data
(63) Continuation of application No. PCT/JP2024/004155, filed on Feb. 7, 2024.

(30) Foreign Application Priority Data
Sep. 7, 2023 (JP) 2023-145014

(51) Int. Cl. H10D 64/66; H10D 30/66; H10D 62/832; H10D 64/68

(52) U.S. Cl. CPC H10D 64/661; H10D 30/66; H10D 62/8325; H10D 64/68

(57) ABSTRACT

According to one embodiment, a semiconductor device includes an element portion. The element portion includes a semiconductor member including a pad portion semiconductor region and a cell semiconductor region, a gate electrode, and a gate pad portion electrically connected to the gate electrode. The gate pad portion includes a first conductive member, and a first member provided between the pad portion semiconductor region and the first conductive member. The first member includes a first region and a second region. The first region and the second region are arranged in a second direction crossing a first direction from the pad portion semiconductor region to the first conductive member. At least a portion of the first conductive member is located between the first region and the second region. A first surface of the at least the portion of the first conductive member includes a first unevenness.

### CROSS-REFERENCE TO RELATED APPLICATIONS

This is a continuation application of International Application PCT/JP2024/004155, filed on Feb. 7, 2024. This application also claims priority to Japanese Patent Application No. 2023-145014, filed on Sep. 7, 2023. The entire contents of which are incorporated herein by reference.

### FIELD

Embodiments described herein generally relate to a semiconductor device.

### BACKGROUND

For example, stable characteristics are desired in semiconductor devices.

### BRIEF DESCRIPTION OF THE DRAWINGS

FIG. 1 is a schematic cross-sectional view illustrating a part of a semiconductor device according to a first embodiment;

FIG. 2 is a schematic cross-sectional view illustrating a part of the semiconductor device according to the first embodiment;

FIG. 3 is a schematic plan view illustrating the semiconductor device according to the first embodiment;

FIG. 4 is a schematic cross-sectional view illustrating a part of a semiconductor device according to a second embodiment;

FIG. 5 is a schematic cross-sectional view illustrating a part of a semiconductor device according to a third embodiment; and

FIG. 6 is a schematic plan view illustrating a semiconductor device according to a fourth embodiment.

### DETAILED DESCRIPTION

According to one embodiment, a semiconductor device includes an element portion. The element portion includes a semiconductor member including a pad portion semiconductor region and a cell semiconductor region, a gate electrode, and a gate pad portion electrically connected to the gate electrode. The gate pad portion includes a first conductive member, and a first member provided between the pad portion semiconductor region and the first conductive member. The first member includes a first region and a second region. The first region and the second region are arranged in a second direction crossing a first direction from the pad portion semiconductor region to the first conductive member. At least a portion of the first conductive member is located between the first region and the second region. A first surface of the at least the portion of the first conductive member includes a first unevenness.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously in an antecedent drawing are marked with like reference numerals, and a detailed description is omitted as appropriate.

### First Embodiment

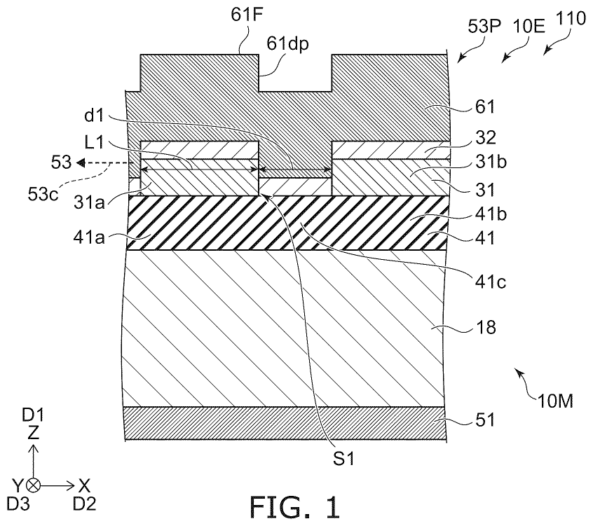

FIG. 1 is a schematic cross-sectional view illustrating a part of a semiconductor device according to a first embodiment.

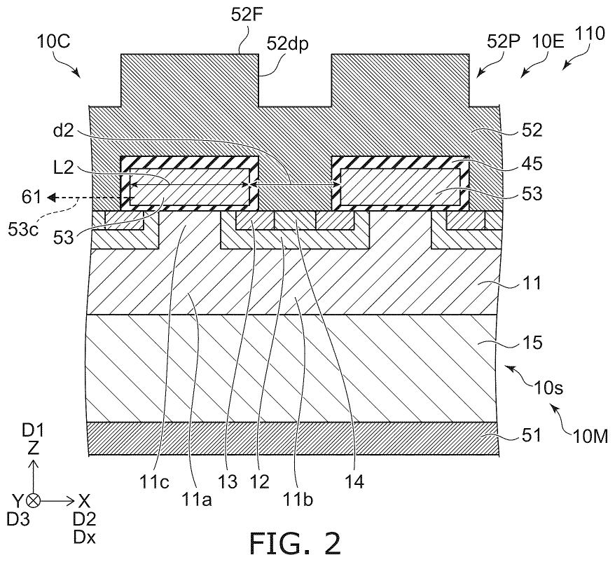

FIG. 2 is a schematic cross-sectional view illustrating a part of the semiconductor device according to the first embodiment.

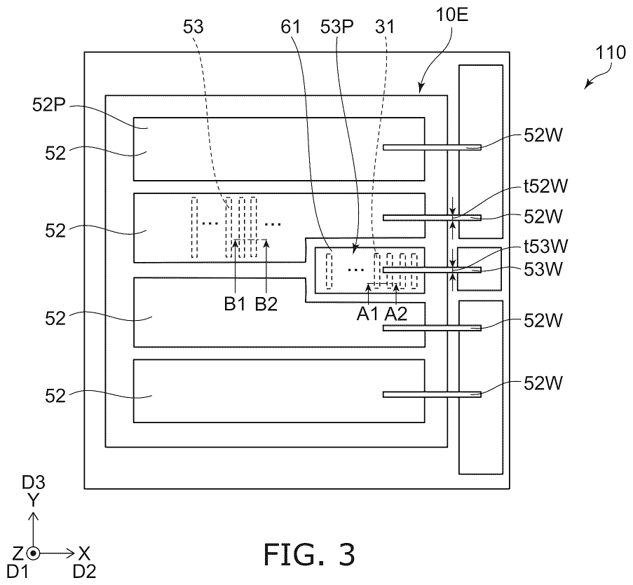

FIG. 3 is a schematic plan view illustrating the semiconductor device according to the first embodiment.

FIG. 1 is a cross-sectional view taken along the line A1-A2 of FIG. 3. FIG. 2 is a cross-sectional view taken along the line B1-B2 of FIG. 3.

As shown in FIGS. 1 to 3, a semiconductor device 110 according to the embodiment includes an element section 10E. The element section 10E includes a semiconductor member 10M, a gate electrode 53, and a gate pad portion 53P.

As shown in FIGS. 1 and 2, the semiconductor member 10M includes a pad portion semiconductor region 18 and a cell semiconductor region 10s. The gate pad portion 53P is electrically connected to the gate electrode 53.

As shown in FIG. 1, the gate pad portion 53P includes a first conductive member 61. For example, the first conductive member 61 is electrically connected to the gate electrode 53 by a connecting layer 53c (see FIGS. 1 and 2). The connecting layer 53c may be provided at a position different from the cross section illustrated in FIGS. 1 and 2. The connecting layer 53c may include, for example, at least one of polysilicon or metal. The first conductive member 61 functions as a pad portion conductive layer.

In the example, the gate pad portion 53P includes a first member 31. The first member 31 is provided between the pad portion semiconductor region 18 and the first conductive member 61. The first member 31 includes a first region 31a and a second region 31b. A second direction D2 from the first region 31a to the second region 31b crosses a first direction D1 from the pad portion semiconductor region 18 to the first conductive member 61.

The first direction D1 is defined as a Z-axis direction. A direction perpendicular to the Z-axis direction is defined as an X-axis direction. A direction perpendicular to the Z-axis direction and the X-axis direction is defined as a Y-axis direction. The second direction D2 may be, for example, the X-axis direction.

At least a portion of the first conductive member 61 is provided between the first region 31a and the second region 31b. A first surface 61F of at least a portion of the first conductive member 61 includes a first unevenness 61dp. The first unevenness 61dp is located above a step S1 provided between the first region 31a and the second region 31b. For example, the first unevenness 61dp reflects the step S1 based on the first region 31a and the second region 31b. For example, the first unevenness 61dp corresponds to the step S1 based on the first region 31a and the second region 31b. The step S1 is formed by, for example, the first region 31a and the second region 31b.

FIG. 2 illustrates the cell portion 10C of the element section 10E. As shown in FIG. 2, the element section 10E further includes a drain electrode 51 and a source electrode 52. For example, the semiconductor member 10M (cell semiconductor region 10s) is provided between the drain electrode 51 and the source electrode 52. The gate electrode 53 is provided between the semiconductor member 10M and the source electrode 52. An insulating layer 45 is provided between the gate electrode 53 and the source electrode 52 and between the gate electrode 53 and the semiconductor member 10M. The source electrode 52 functions as the source pad portion 52P.

A current flowing between the drain electrode 51 and the source electrode 52 can be controlled by a potential of the gate electrode 53. The semiconductor device 110 is a transistor. An example of the cell portion 10C will be described later.

In the embodiment, in the gate pad portion 53P, the first surface 61F of the first conductive member 61 includes the first unevenness 61dp. Thereby, it has been found that various defects in wire bonding can be suppressed. It is considered that this is because an appropriate condition in the wire bonding step approach (or coincide with) an appropriate condition in the wire bonding step in the cell portion 10C by providing the first unevenness 61dp.

As illustrated in FIG. 2, in the cell portion 10C, a second unevenness 52dp is formed on the second surface 52F of the source electrode 52 due to the plurality of gate electrodes 53. There is an appropriate condition (for example, a second condition) in the wire bonding on the second surface 52F including the second unevenness 52dp. In the embodiment, by providing the first unevenness 61dp on the first surface 61F of the first conductive member 61, an appropriate condition (for example, the first condition) can coincide with (or be close to) the second condition in the wire bonding on the first surface 61F. Thereby, various defects (for example, peeling or cracking) in the wire bonding step can be suppressed. Various defects are suppressed, and stable characteristics are obtained. According to the embodiment, it is possible to provide a semiconductor device capable of obtaining stable characteristics.

When the first condition coincides with or is close to the second condition, bonding with high productivity can be performed.

According to the embodiment, defects in the wire bonding step are suppressed, and a high yield is obtained. According to the embodiment, high reliability is obtained.

As shown in FIG. 3, for example, the gate electrode 53 extends along a third direction D3. The third direction D3 crosses a plane including the first direction D1 and the second direction D2. The third direction D3 may be, for example, the Y-axis direction. As shown in FIG. 3, the first region 31a and the second region 31b may extend along the third direction D3.

When the gate electrode 53 extends along the third direction D3, the second unevenness 52dp of the second surface 52F of the source electrode 52 preferably extends along the third direction D3. When the first region 31a and the second region 31b extend along the third direction D3, the first unevenness 61dp of the first surface 61F of the first conductive member 61 extends along the third direction D3. Since the direction of the first unevenness 61dp is along to the direction of the second unevenness 52dp, the bonding conditions are easily matched. For example, the characteristics become are more stable. For example, defects are further suppressed.

In the embodiment, the direction of the first unevenness 61dp may cross the direction of the second unevenness 52dp. In the embodiment, the first unevenness 61dp may be along any direction along the X-Y plane. The first unevenness 61dp may have a lattice shape or an island shape along two directions along the X-Y plane.

As shown in FIG. 1, a first length L1 and a first distance d1 may be defined. As shown in FIG. 2, a second length L2 and a second distance d2 may be defined. A first ratio of the first length L1 to the first distance d1 is preferably equal to or close to a second ratio of the second length L2 to the second distance d2. Thereby, appropriate bonding conditions in the cell portion 10C (the source pad portion 52P) and the gate pad portion 53P coincide with each other. Alternatively, it becomes easy to make these conditions suitable close to each other.

The first length L1 illustrated in FIG. 1 is a length of the first region 31a along the second direction D2. The first distance d1 is a distance along the second direction D2 between the first region 31a and the second region 31b. A length of the second region 31b in the second direction D2 may be the same as the first length L1.

On the other hand, as shown in FIGS. 2 and 3, a plurality of gate electrodes 53 are provided. The plurality of gate electrodes 53 are arranged in a crossing direction Dx crosses the first direction D1. In the example, the crossing direction Dx is the second direction D2. The second length L2 is a length of one of the plurality of gate electrodes 53 in the crossing direction Dx. Another one of the plurality of gate electrodes 53 is next to the one of the plurality of gate electrodes 53. The second distance d2 is a distance along the crossing direction Dx between the other one of the plurality of gate electrodes 53 and the one of the plurality of gate electrodes 53.

The first ratio and the second ratio are defined based on such lengths. In the embodiment, the first ratio is preferably not less than 0.5 times and not more than 1.5 times the second ratio. Thereby, appropriate conditions for bonding are likely to match or be close to each other.

In one example, the first member 31 includes, for example, polysilicon.

As shown in FIG. 1, the gate pad portion 53P may further include a first insulating member 41. The first insulating member 41 includes a first insulating region 41a, a second insulating region 41b, and a third insulating region 41c. The first insulating region 41a is provided between the pad portion semiconductor region 18 and the first region 31a in the first direction D1. The second insulating region 41b is provided between the pad portion semiconductor region 18 and the second region 31b in the first direction D1. The third insulating region 41c is provided between the first insulating region 41a and the second insulating region 41b in the second direction D2. In one example, the first insulating member 41 includes, for example, silicon oxide.

As shown in FIG. 1, the gate pad portion 53P may further include a second member 32. The second member 32 is provided between the first region 31a and the first conductive member 61 in the first direction D1, between the second region 31b and the first conductive member 61 in the first direction D1, and between the third insulating region 41c and the first conductive member 61 in the first direction D1.

The second member 32 may include, for example, at least one selected from the group consisting of Ti, Mo, V, and TiW. For example, high adhesion is easily obtained.

In the semiconductor device 110, a thickness of the first insulating member 41 may be, for example, not less than 200 nm and not more than 1000 nm. A thickness of the first member 31 may be, for example, not less than 250 nm and not more than 450 nm. A thickness of the second member 32 may be, for example, not less than 100 nm and not more than 200. A thickness of the first conductive member 61 may be, for example, not less than 3500 nm and not more than 5000 nm. These thicknesses are lengths along the first direction D1.

As shown in FIG. 3, the semiconductor device 110 may include the source electrode 52, a source connecting wire 52W, and a gate connecting wire 53W. The source connecting wire 52W is electrically connected to the source electrode 52. The gate connecting wire 53W is electrically connected to the gate pad portion 53P. A first width t53W of the gate connecting wire 53W may be equal to or close to a second width t52W of the source connecting wire 52W. As a result, the appropriate bonding conditions for both can be matched or approximated. For example, the first width t53W is not less than 0.8 times and not more than 1.2 times the second width t52W. The materials of these wires may be the same as each other.

As shown in FIG. 2, the cell semiconductor region 10s may include a first semiconductor region 11 of a first conductivity type, a second semiconductor region 12 of a second conductivity type, and a third semiconductor region 13 of the first conductivity type. In this example, the cell semiconductor region 10s further includes a fourth semiconductor region 14 of the second conductivity type. In this example, the cell semiconductor region 10s further includes a fifth semiconductor region 15 of the first conductivity type.

The first conductivity type is one of n-type and p-type. The second conductivity type is the other of the n-type and the p-type. Hereinafter, the first conductivity type is n-type, and the second conductivity type is p-type.

The first semiconductor region 11 includes, for example, a first partial region 11a, a second partial region 11b, and a third partial region 11c. A direction from the first partial region 11a to the second partial region 11b is along the crossing direction Dx (for example, the second direction D2). The third partial region 11c is provided between the first partial region 11a and the gate electrode 53 in the first direction D1.

A direction from the second partial region 11b to the second semiconductor region 12 is along the first direction D1. A portion of the second semiconductor region 12 is provided between the third partial region 11c and the third semiconductor region 13 in the crossing direction Dx (e.g., the second direction D2). A portion of the second semiconductor region 12 is provided between the second partial region 11b and the third semiconductor region 13 in the first direction D1.

The third semiconductor region 13 is provided between the third partial region 11c and the fourth semiconductor region 14 in the crossing direction Dx. A portion of the second semiconductor region 12 is provided between the third partial region 11c and the third semiconductor region 13 in the crossing direction Dx.

The source electrode 52 is electrically connected to the third semiconductor region 13 and the fourth semiconductor region 14. The source electrode 52 is in contact with the third semiconductor region 13 and the fourth semiconductor region 14.

A portion of the insulating layer 45 is provided between the third partial region 11c and the gate electrode 53. A portion of the insulating layer 45 functions as a gate insulating film. The portion of the insulating layer 45 includes silicon oxide.

In the semiconductor device 110, an impurity concentration of the first conductivity type in the third semiconductor region 13 is higher than an impurity concentration of the first conductivity type in the first semiconductor region 11. An impurity concentration of the second conductivity type in the fourth semiconductor region 14 is higher than an impurity concentration of the second conductivity type in the second semiconductor region 12.

The fifth semiconductor region 15 is provided between the drain electrode 51 and the first semiconductor region 11. The fifth semiconductor region 15 is of the first conductivity type. An impurity concentration of the first conductivity type in the fifth semiconductor region 15 is higher than the impurity concentration of the first conductivity type in the first semiconductor region 11.

### Second Embodiment

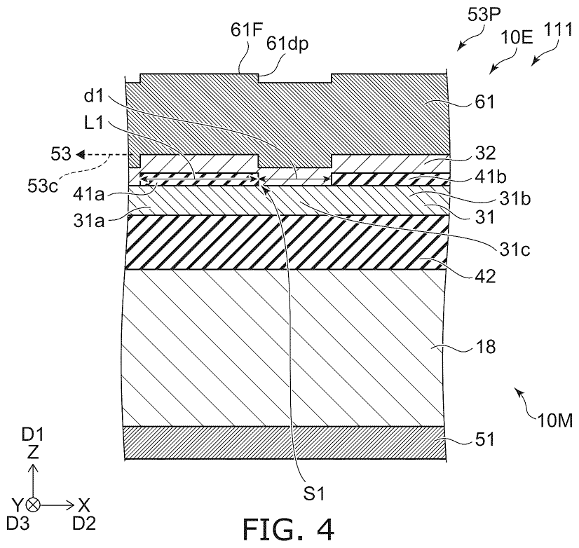

FIG. 4 is a schematic cross-sectional view illustrating a part of a semiconductor device according to a second embodiment.

As shown in FIG. 4, in a semiconductor device 111 according to the embodiment, the element section 10E includes the gate pad portion 53P. The configuration of the gate pad portion 53P in the semiconductor device 111 is different from the configuration of the gate pad portion 53P in the first embodiment. The configuration of the semiconductor device 111 except for this may be the same as the configuration of the semiconductor device 110.

Also in the semiconductor device 111, the element section 10E includes the semiconductor member 10M, the gate electrode 53 (see FIG. 2), and the gate pad portion 53P. The semiconductor member 10M includes the pad portion semiconductor region 18 and the cell semiconductor region 10s (see FIG. 2). The gate pad portion 53P is electrically connected to the gate electrode 53.

As shown in FIG. 4, the gate pad portion 53P includes the first conductive member 61 and the first insulating member 41. The first insulating member 41 is provided between the pad portion semiconductor region 18 and the first conductive member 61. The first insulating member 41 includes the first insulating region 41a and the second insulating region 41b. The second direction D2 from the first insulating region 41a to the second insulating region 41b crosses the first direction D1 from the pad portion semiconductor region 18 to the first conductive member 61. The second insulating region 41b is separated from the first insulating region 41a in the second direction D2.

As shown in FIG. 4, the first surface 61F of the first conductive member 61 includes the first unevenness 61dp. The first unevenness 61dp reflects the step S1 based on the first insulating region 41a and the second insulating region 41b. For example, the first unevenness 61dp corresponds to the step S1 based on the first insulating region 41a and the second insulating region 41b. The step S1 is formed by, for example, the first insulating region 41a and the second insulating region 41b.

In the semiconductor device 111 as well, the appropriate bonding condition in the gate pad portion 53P coincides with or is close to the appropriate bonding condition in the cell portion 10C (source pad portion 52P). Defects in bonding are suppressed. Stable characteristics are obtained. According to the embodiment, it is possible to provide a semiconductor device capable of obtaining stable characteristics. Bonding can be performed with high productivity. A high yield is obtained. High reliability is obtained.

In the semiconductor device 111 as well, the gate electrode 53 extends along the third direction D3 crossing the plane including the first direction D1 and the second direction D2 (see FIG. 3). The first insulating region 41a and the second insulating region 41b preferably extend along the third direction D3.

As shown in FIG. 4, also in the semiconductor device 111, the first length L1 and the first distance d1 can be defined. In the semiconductor device 111, the second length L2 and the second distance d2 can be defined (see FIG. 2). As shown in FIG. 4, the first length L1 is the length of the first insulating region 41a along the second direction D2. The first distance d1 is a distance along the second direction D2 between the first insulating region 41a and the second insulating region 41b.

In the semiconductor device 111, a plurality of gate electrodes 53 may be provided (see FIG. 2). The plurality of gate electrodes 53 are arranged in the crossing direction Dx crossing the first direction D1. The second distance d2 is the length of one of the plurality of gate electrodes 53 along the crossing direction Dx. Another one of the plurality of gate electrodes 53 is next to the one of the plurality of gate electrodes 53. The second distance d2 is the distance along the crossing direction Dx between the other one of the plurality of gate electrodes 53 and the one of the plurality of gate electrodes 53 (see FIG. 2).

In the semiconductor device 111, the first ratio of the first length L1 to the first distance d1 may be not less than 0.5 times and not more than 1.5 times the second ratio of the second length L2 to the second distance d2.

As shown in FIG. 4, in the semiconductor device 111, the gate pad portion 53P may further include the first member 31. The first member 31 includes the first region 31a, the second region 31b, and the third region 31c. The first region 31a is provided between the pad portion semiconductor region 18 and the first insulating region 41a. The second region 31b is provided between the pad portion semiconductor region 18 and the second insulating region 41b. The third region 31c is provided between the first region 31a and the second region 31b in the second direction D2. The first insulating member 41 is not provided between the third region 31c and the first conductive member 61 in the first direction D1.

As shown in FIG. 4, in the semiconductor device 111, the gate pad portion 53P may further include the second member 32. The second member 32 is provided between the first insulating region 41a and the first conductive member 61 in the first direction D1, between the second insulating region 41b and the first conductive member 61 in the first direction D1, and between the third region 31c and the first conductive member 61 in the first direction D1. The second member 32 may include, for example, at least one selected from the group consisting of Ti, Mo, V, and TiW. For example, high adhesion is easily obtained.

As shown in FIG. 4, in the semiconductor device 111, the gate pad portion 53P may further include the second insulating member 42. The second insulating member 42 is provided between the pad portion semiconductor region 18 and the first member 31. The second insulating member 42 includes, for example, silicon oxide.

### Third Embodiment

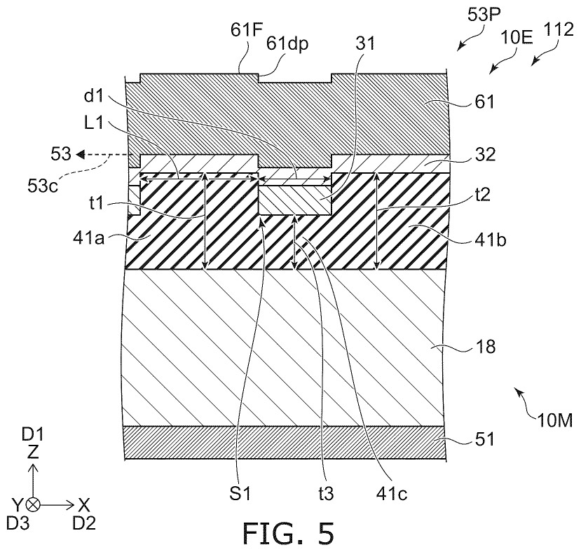

FIG. 5 is a schematic cross-sectional view illustrating a part of a semiconductor device according to a third embodiment.

As shown in FIG. 5, in a semiconductor device 112 according to the embodiment, the element section 10E includes the gate pad portion 53P. The configuration of the gate pad portion 53P in the semiconductor device 112 is different from the configuration of the gate pad portion 53P in the first embodiment. The configuration of the semiconductor device 112 except for this may be the same as the configuration of the semiconductor device 110.

In the semiconductor device 112 as well, the element section 10E includes the semiconductor member 10M, the gate electrode 53 (see FIG. 2), and the gate pad portion 53P. The semiconductor member 10M includes the pad portion semiconductor region 18 and the cell semiconductor region 10s (see FIG. 2). The gate pad portion 53P is electrically connected to the gate electrode 53.

As shown in FIG. 5, in the semiconductor device 112, the gate pad portion 53P includes the first conductive member 61 and the first insulating member 41. The first insulating member 41 is provided between the pad portion semiconductor region 18 and the first conductive member 61.

As shown in FIG. 5, in the semiconductor device 112, the first insulating member 41 includes the first insulating region 41a, the second insulating region 41b, and the third insulating region 41c. The second direction D2 from the first insulating region 41a to the second insulating region 41b crosses the first direction D1 from the pad portion semiconductor region 18 to the first conductive member 61.

A position of the third insulating region 41c in the second direction D2 is located between a position of the first insulating region 41a in the second direction D2 and a position of the second insulating region 41b in the second direction D2. A third thickness t3 of the third insulating region 41c in the first direction D1 is thinner than a first thickness t1 of the first insulating region 41a in the first direction D1. The third thickness t3 is thinner than a second thickness t2 of the second insulating region 41b in the first direction D1.

As shown in FIG. 5, the first surface 61F of the first conductive member 61 includes the first unevenness 61dp. The first unevenness 61dp reflects, for example, the step S1 based on the first insulating region 41a, the second insulating region 41b, and the third insulating region 41c. The first unevenness 61dp reflects, for example, the step S1 based on the first insulating region 41a, the second insulating region 41b, and the third insulating region 41c. The step S1 is formed by, for example, the first insulating region 41a, the second insulating region 41b, and the third insulating region 41c. In the semiconductor device 112 as well, stable characteristics are obtained. According to the embodiment, it is possible to provide a semiconductor device capable of obtaining stable characteristics. Bonding can be performed with high productivity. A high yield is obtained. High reliability is obtained.

Also in the semiconductor device 112, the gate electrode 53 extends along the third direction D3 crossing a plane including the first direction D1 and the second direction D2 (see FIG. 2). The first insulating region 41a and the second insulating region 41b preferably extend along the third direction D3.

As shown in FIG. 5, in the semiconductor device 112 as well, the first length L1 and the first distance d1 can be defined. In the semiconductor device 112, the second length L2 and the second distance d2 can be defined (see FIG. 2). As shown in FIG. 5, the first length L1 is the length of the first insulating region 41a along the second direction D2. The first distance d1 is the distance along the second direction D2 between the first insulating region 41a and the second insulating region 41b.

In the semiconductor device 112, the plurality of gate electrodes 53 may be provided (see FIG. 2). The plurality of gate electrodes 53 are arranged in the crossing direction Dx crossing the first direction D1. The second distance d2 is the length of one of the plurality of gate electrodes 53 along the crossing direction Dx. Another one of the plurality of gate electrodes 53 is next to the one of the plurality of gate electrodes 53. The second distance d2 is the distance along the crossing direction Dx between the other one of the plurality of gate electrodes 53 and the one of the plurality of gate electrodes 53 (see FIG. 2).

In the semiconductor device 112, the first ratio of the first length L1 to the first distance d1 may be not less than 0.5 times and not more than 1.5 times the second ratio of the second length L2 to the second distance d2.

As shown in FIG. 5, in the semiconductor device 112, the gate pad portion 53P may further include the first member 31. At least a portion of the first member 31 is provided between the first insulating region 41a and the second insulating region 41b in the second direction D2. At least a portion of the first member 31 is provided between the third insulating region 41c and the first conductive member 61 in the first direction D1. The first member 31 may include, for example, polysilicon.

As shown in FIG. 5, in the semiconductor device 112, the gate pad portion 53P may further include the second member 32. The second member 32 is provided between the first insulating region 41a and the first conductive member 61 in the first direction D1, between the second insulating region 41b and the first conductive member 61 in the first direction D1, and between the first member 31 and the first conductive member 61 in the first direction D1. The second member 32 may include, for example, at least one selected from the group consisting of Ti, Mo, V, and TiW. For example, high adhesion is easily obtained.

The semiconductor device 111 and the semiconductor device 112 may include the source electrode 52, the source connecting wire 52W, and the gate connecting wire 53W (see FIG. 3). The source connecting wire 52W is electrically connected to the source electrode 52. The gate connecting wire 53W is electrically connected to the gate pad portion 53P. The first width t53W of the gate connecting wire 53W may be equal to or close to the second width t52W of the source connecting wire 52W. As a result, the appropriate bonding conditions for both can be matched or approximated. For example, the first width t53W is not less than 0.8 times and not more than 1.2 times the second width t52W. The materials of these wires may be the same as each other.

### Fourth Embodiment

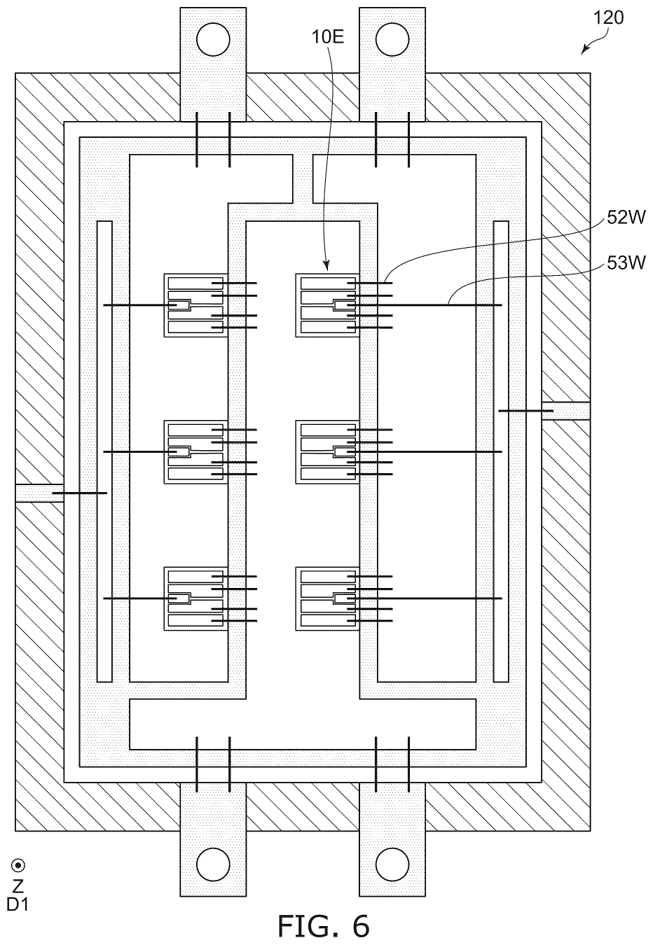

FIG. 6 is a schematic plan view illustrating a semiconductor device according to a fourth embodiment.

As shown in FIG. 6, in a semiconductor device 120 according to the embodiment, a plurality of element sections 10E are provided. The configurations of the element sections 10E in the semiconductor device 110, the semiconductor device 111, and the semiconductor device 112 are applied to the plurality of element sections 10E. The semiconductor device 120 is, for example, a semiconductor module. When the plurality of element sections 10E are provided, the number of bonding wires (such as the source connecting wire 52W and the gate connecting wire 53W) becomes large. High manufacturing efficiency can be obtained by making the conditions of the bonding step uniform in many bonding wires. The effect of providing the first unevenness 61dp is further exerted.

In the embodiment, for example, the semiconductor member 10M (the pad portion semiconductor region 18 and the cell semiconductor region 10s) includes SiC. The semiconductor member 10M may include at least one selected from the group consisting of 4H—SiC, 6H—SiC, and 3C—SiC. The semiconductor member 10M includes a crystal.

For example, the impurity of the first conductivity type includes at least one selected from the group consisting of N, P, and As. For example, the impurity of the second conductivity type includes at least one selected from the group consisting of B, Al, and Ga.

In the embodiment, information on the length and the thickness is obtained by electron microscope observation or the like. The information on the composition of the material is obtained by SIMS (Secondary Ion Mass Spectrometry), EDX (Energy dispersive X-ray spectroscopy), or the like.

The embodiments may include the following Technical proposals:

### (Technical Proposal 1)

A semiconductor device, comprising:
an element portion including:
   a semiconductor member including a pad portion semiconductor region and a cell semiconductor region,
   a gate electrode, and
   a gate pad portion electrically connected to the gate electrode,
the gate pad portion including:
   a first conductive member, and
   a first member provided between the pad portion semiconductor region and the first conductive member,
the first member including a first region and a second region, the first region and the second region being arranged in a second direction crossing a first direction from the pad portion semiconductor region to the first conductive member,
at least a portion of the first conductive member being located between the first region and the second region, and
a first surface of the at least the portion of the first conductive member including a first unevenness.

### (Technical Proposal 2)

The semiconductor device according to Technical proposal 1, wherein
the gate electrode extends along a third direction crossing a plane including the first direction and the second direction, and
the first region and the second region extend along the third direction.

### (Technical Proposal 3)

The semiconductor device according to Technical proposal 1, wherein
the first member includes polysilicon.

### (Technical Proposal 4)

The semiconductor device according to any one of Technical proposals 1-3, wherein
the gate pad portion further includes a first insulating member,
the first insulating member includes a first insulating region, a second insulating region, and a third insulating region,
the first insulating region is provided between the pad semiconductor region and the first region in the first direction,
the second insulating region is provided between the pad semiconductor region and the second region in the first direction, and
the third insulating region is provided between the first insulating region and the second insulating region in the second direction.

### (Technical Proposal 5)

The semiconductor device according to Technical proposal 4, wherein
the gate pad portion further includes a second member,
the second member is provided between the first region and the first conductive member in the first direction, between the second region and the first conductive member in the first direction, and between the third insulating region and the first conductive member in the first direction.

### (Technical Proposal 6)

The semiconductor device according to any one of Technical proposals 1-5, wherein
a first ratio of a first length to a first distance is not less than 0.5 times and not more than 1.5 times a second ratio of a second length to a second distance,
the first length is a length of the first region along the second direction,
the first distance is a distance along the second direction between the first region and the second region,
a plurality of the gate electrodes are provided,
the plurality of gate electrodes are arranged in a crossing direction crossing the first direction, and
the second distance is a length of one of the plurality of gate electrodes in the crossing direction,
another one of the plurality of gate electrodes is next to the one of the plurality of gate electrodes, and
the second distance is a distance along the crossing direction between the other one of the plurality of gate electrodes and the one of the plurality of gate electrodes.

### (Technical Proposal 7)

A semiconductor device, comprising:
an element portion including:
   a semiconductor member including a pad portion semiconductor region and a cell semiconductor region,
   a gate electrode, and
   a gate pad portion electrically connected to the gate electrode,
the gate pad portion including:
   a first conductive member, and
   a first member provided between the pad portion semiconductor region and the first conductive member,
the first insulating member including a first insulating region and a second insulating region, the first insulating region and the second insulating region being arranged in a second direction crossing a first direction from the pad portion semiconductor region to the first conductive member,
the second insulating region being separated from the first insulating region in the second direction, and
a first surface of the first conductive member includes a first evenness.

### (Technical Proposal 8)

The semiconductor device according to Technical proposal 7, wherein
the gate electrode extends along a third direction crossing a plane including the first direction and the second direction, and
the first insulating region and the second insulating region extend along the third direction.

### (Technical Proposal 9)

The semiconductor device according to Technical proposal 7 or 8, wherein
the gate pad portion further includes a first member,
the first member includes a first region, a second region, and a third region,
the first region is provided between the pad semiconductor region and the first insulating region,
the second region is provided between the pad semiconductor region and the second insulating region, and
the third region is provided between the first region and the second region in the second direction,
in the first direction, the first insulating member is not provided between the third region and the first conductive member.

### (Technical Proposal 10)

The semiconductor device according to Technical proposal 9, wherein
the gate pad portion further includes a second member, and
the second member is provided between the first insulating region and the first conductive member in the first direction, between the second insulating region and the first conductive member in the first direction, and between the third region and the first conductive member in the first direction.

### (Technical Proposal 11)

The semiconductor device according to Technical proposal 9 or 10, wherein
the gate pad portion further includes a second insulating member, and
the second insulating member is provided between the pad semiconductor region and the first member.

### (Technical Proposal 12)

The semiconductor device according to any one of Technical proposals 7-11, wherein
a first ratio of a first length to a first distance is not less than 0.5 times and not more than 1.5 times a second ratio of a second length to a second distance,
the first length is a length of the first insulating region along the second direction,
the first distance is a distance along the second direction between the first insulating region and the second insulating region,
a plurality of the gate electrodes are provided,
the plurality of gate electrodes are arranged in a crossing direction crossing the first direction,
the second distance is a length of one of the plurality of gate electrodes along the crossing direction,
another one of the plurality of gate electrodes is next to the one of the plurality of gate electrodes, and
the second distance is a distance along the crossing direction between the other one of the plurality of gate electrodes and the one of the plurality of gate electrodes.

### (Technical Proposal 13)

A semiconductor device, comprising:
an element portion including:
   a semiconductor member including a pad portion semiconductor region and a cell semiconductor region,
   a gate electrode, and
   a gate pad portion electrically connected to the gate electrode,
the gate pad portion including:
   a first conductive member, and
   a first insulating member provided between the pad portion semiconductor region and the first conductive member,
the first insulating member including a first insulating region, a second insulating region, and a third insulating region,
a second direction from the first insulating region to the second insulating region crossing a first direction from the pad portion semiconductor region to the first conductive member,
a position of the third insulating region in the second direction being between a position of the first insulating region in the second direction and a position of the second insulating region in the second direction,
a third thickness of the third insulating region in the first direction being less than a first thickness of the first insulating region in the first direction,
the third thickness being less than a second thickness of the second insulating region in the first direction, and
a first surface of the first conductive member including a first unevenness.

### (Technical Proposal 14)

The semiconductor device according to Technical proposal 13, wherein
the gate electrode extends along a third direction crossing a plane including the first direction and the second direction,
the first insulating region and the second insulating region extend along the third direction.

### (Technical Proposal 15)

The semiconductor device according to Technical proposal 13 or 14, wherein
the gate pad portion further includes a first member,
at least a portion of the first member is provided between the first insulating region and the second insulating region in the second direction,
the at least the portion of the first member is provided between the third insulating region and the first conductive member in the first direction, and
the first member includes polysilicon.

### (Technical Proposal 16)

The semiconductor device according to Technical proposal 15, wherein
the gate pad portion further includes a second member,
the second member is provided between the first insulating region and the first conductive member in the first direction, between the second insulating region and the first conductive member in the first direction, and between the first member and the first conductive member in the first direction.

### (Technical Proposal 17)

The semiconductor device according to any one of Technical proposals 13-16, wherein
a first ratio of a first length to a first distance is not less than 0.5 times and not more than 1.5 times a second ratio of a second length to a second distance,
the first length is a length of the first insulating region along the second direction,
the first distance is a distance along the second direction between the first insulating region and the second insulating region,
a plurality of the gate electrodes are provided,
the plurality of gate electrodes are arranged in a crossing direction crossing the first direction,
the second distance is a length of one of the plurality of gate electrodes along the crossing direction,
another one of the plurality of gate electrodes is next to the one of the plurality of gate electrodes,
the second distance is a distance along the crossing direction between the other one of the plurality of gate electrodes and the one of the plurality of gate electrodes.

### (Technical Proposal 18)

The semiconductor device according to any one of Technical proposals 1-17, further comprising:
a source electrode;
a source connecting wire electrically connected to the source electrode; and
a gate connecting wire electrically connected to the gate pad portion,
a first width of the gate connecting wire being not less than 0.8 times and not more than 1.2 times a second width of the source connecting wire.

### (Technical Proposal 19)

The semiconductor device according to Technical proposal 18, wherein
a plurality of the element sections are provided.

### (Technical Proposal 20)

The semiconductor device according to any one of Technical proposals 1-19, wherein
the semiconductor member includes SiC.

According to the embodiment, a semiconductor device with improved characteristics can be provided.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the semiconductor devices such as electrodes, semiconductor members, conductive members, insulating members, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices practicable by an appropriate design modification by one skilled in the art based on the semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
an element portion including:
a semiconductor member including a pad portion semiconductor region and a cell semiconductor region,
a gate electrode, and
a gate pad portion electrically connected to the gate electrode,
the gate pad portion including:
a first conductive member, and
a first member provided between the pad portion semiconductor region and the first conductive member,
the first member including a first region and a second region, the first region and the second region being arranged in a second direction crossing a first direction from the pad portion semiconductor region to the first conductive member,
at least a portion of the first conductive member being located between the first region and the second region, and
a first surface of the at least the portion of the first conductive member including a first unevenness.

2. The device according to claim 1, wherein
the gate electrode extends along a third direction crossing a plane including the first direction and the second direction, and
the first region and the second region extend along the third direction.

3. The device according to claim 1, wherein
the first member includes polysilicon.

4. The device according to claim 1, wherein
the gate pad portion further includes a first insulating member,
the first insulating member includes a first insulating region, a second insulating region, and a third insulating region,
the first insulating region is provided between the pad semiconductor region and the first region in the first direction,
the second insulating region is provided between the pad semiconductor region and the second region in the first direction, and
the third insulating region is provided between the first insulating region and the second insulating region in the second direction.

5. The device according to claim 4, wherein
the gate pad portion further includes a second member,
the second member is provided between the first region and the first conductive member in the first direction, between the second region and the first conductive member in the first direction, and between the third insulating region and the first conductive member in the first direction.

6. The device according to claim 1, wherein
a first ratio of a first length to a first distance is not less than 0.5 times and not more than 1.5 times a second ratio of a second length to a second distance,
the first length is a length of the first region along the second direction,
the first distance is a distance along the second direction between the first region and the second region,
a plurality of the gate electrodes are provided,
the plurality of gate electrodes are arranged in a crossing direction crossing the first direction, and
the second distance is a length of one of the plurality of gate electrodes in the crossing direction,
another one of the plurality of gate electrodes is next to the one of the plurality of gate electrodes, and
the second distance is a distance along the crossing direction between the other one of the plurality of gate electrodes and the one of the plurality of gate electrodes.

7. A semiconductor device, comprising:
an element portion including:
a semiconductor member including a pad portion semiconductor region and a cell semiconductor region,
a gate electrode, and
a gate pad portion electrically connected to the gate electrode,
the gate pad portion including:
a first conductive member, and
a first member provided between the pad portion semiconductor region and the first conductive member,
the first insulating member including a first insulating region and a second insulating region, the first insulating region and the second insulating region being arranged in a second direction crossing a first direction from the pad portion semiconductor region to the first conductive member,
the second insulating region being separated from the first insulating region in the second direction, and
a first surface of the first conductive member includes a first evenness.

8. The device according to claim 7, wherein
the gate electrode extends along a third direction crossing a plane including the first direction and the second direction, and
the first insulating region and the second insulating region extend along the third direction.

9. The device according to claim 7, wherein
the gate pad portion further includes a first member,
the first member includes a first region, a second region, and a third region,
the first region is provided between the pad semiconductor region and the first insulating region,
the second region is provided between the pad semiconductor region and the second insulating region, and
the third region is provided between the first region and the second region in the second direction,
in the first direction, the first insulating member is not provided between the third region and the first conductive member.

10. The device according to claim 9, wherein
the gate pad portion further includes a second member, and
the second member is provided between the first insulating region and the first conductive member in the first direction, between the second insulating region and the first conductive member in the first direction, and between the third region and the first conductive member in the first direction.

11. The device according to claim 9, wherein
the gate pad portion further includes a second insulating member, and
the second insulating member is provided between the pad semiconductor region and the first member.

12. The device according to claim 7, wherein
a first ratio of a first length to a first distance is not less than 0.5 times and not more than 1.5 times a second ratio of a second length to a second distance,
the first length is a length of the first insulating region along the second direction,
the first distance is a distance along the second direction between the first insulating region and the second insulating region,
a plurality of the gate electrodes are provided,
the plurality of gate electrodes are arranged in a crossing direction crossing the first direction,
the second distance is a length of one of the plurality of gate electrodes along the crossing direction,
another one of the plurality of gate electrodes is next to the one of the plurality of gate electrodes, and
the second distance is a distance along the crossing direction between the other one of the plurality of gate electrodes and the one of the plurality of gate electrodes.

13. A semiconductor device, comprising:
an element portion including:
a semiconductor member including a pad portion semiconductor region and a cell semiconductor region,
a gate electrode, and
a gate pad portion electrically connected to the gate electrode,
the gate pad portion including:
a first conductive member, and
a first insulating member provided between the pad portion semiconductor region and the first conductive member,
the first insulating member including a first insulating region, a second insulating region, and a third insulating region,
a second direction from the first insulating region to the second insulating region crossing a first direction from the pad portion semiconductor region to the first conductive member,
a position of the third insulating region in the second direction being between a position of the first insulating region in the second direction and a position of the second insulating region in the second direction,
a third thickness of the third insulating region in the first direction being less than a first thickness of the first insulating region in the first direction,
the third thickness being less than a second thickness of the second insulating region in the first direction, and
a first surface of the first conductive member including a first unevenness.

14. The device according to claim 13, wherein
the gate electrode extends along a third direction crossing a plane including the first direction and the second direction,
the first insulating region and the second insulating region extend along the third direction.

15. The device according to claim 13, wherein
the gate pad portion further includes a first member,
at least a portion of the first member is provided between the first insulating region and the second insulating region in the second direction,
the at least the portion of the first member is provided between the third insulating region and the first conductive member in the first direction, and
the first member includes polysilicon.

16. The device according to claim 15, wherein
the gate pad portion further includes a second member,
the second member is provided between the first insulating region and the first conductive member in the first direction, between the second insulating region and the first conductive member in the first direction, and between the first member and the first conductive member in the first direction.

17. The device according to a claim 13, wherein
a first ratio of a first length to a first distance is not less than 0.5 times and not more than 1.5 times a second ratio of a second length to a second distance,
the first length is a length of the first insulating region along the second direction,
the first distance is a distance along the second direction between the first insulating region and the second insulating region,
a plurality of the gate electrodes are provided,
the plurality of gate electrodes are arranged in a crossing direction crossing the first direction,
the second distance is a length of one of the plurality of gate electrodes along the crossing direction,
another one of the plurality of gate electrodes is next to the one of the plurality of gate electrodes,
the second distance is a distance along the crossing direction between the other one of the plurality of gate electrodes and the one of the plurality of gate electrodes.

18. The device according to claim 1, further comprising:
a source electrode;
a source connecting wire electrically connected to the source electrode; and
a gate connecting wire electrically connected to the gate pad portion,
a first width of the gate connecting wire being not less than 0.8 times and not more than 1.2 times a second width of the source connecting wire.

19. The device according to claim 18, wherein
a plurality of the element sections are provided.

20. The device according to claim 1, wherein
the semiconductor member includes SiC.
